(19) United States
(12) Patent Application Publication
(10) Pub. No.: US 2005/0147256 A1
(43) Pub. Date: Jul. 7, 2005

(54) Automated presentation of entertainment content in response to received ambient audio

(76) Inventors: Geoffrey W. Peters, Portland, OR (US); James Okuley, Portland, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/749,979

(22) Filed: Dec. 30, 2003

(51) Int. Cl. H04R 29/00; H03G 3/20

(52) U.S. Cl. 381/56; 381/57

(57) ABSTRACT

In some embodiments an apparatus includes an acoustic analyzer to identify received ambient audio and a content parser. The content parser is to select content associated with the identified audio for presentation of the content to a user. Other embodiments are described and claimed.

### TECHNICAL FIELD

The inventions generally relate to presentation of entertainment content in response to received ambient audio.

### BACKGROUND

With the advent of Napster and other peer-to-peer applications, the illegal distribution of audio files has reached epidemic proportions in the last several years. One way to combat this problem is the ability to acoustically analyze an audible wave pattern and generate a unique small “fingerprint” or “thumbprint” for that audio sample. The audio sample may then be compared to a huge database of fingerprints for all known music recordings. Such a database already exists in efforts to combat music piracy.

One product that has been advertised to identify an unknown audio sample is by Audible Magic Corporation, 985 University Avenue, Suite 35, Los Gatos, Calif. 95032. Audible Magic Corporation advertises on their web site content-based identification software that can be integrated into other applications or devices. The software can scan a file or listen to an audio stream, derive fingerprints that will be used to identify the audio, and create an XML package that may be sent to ID servers via HTTP. A reference database maintained by Audible Magic is used to provide positive identification information with a high level of data integrity using fingerprint information.

Another product that has been advertised to identify an audio sample is an AudioID System (Automatic Identification/Fingerprinting of Audio) by Fraunhofer Institut of Integrated Circuits IIS. The AudioID System is described on the Fraunhofer web site as performing an automatic identification/recognition of audio data based on a database of registered works and delivering the required information (that is, title or name of the artist) in real-time. It is suggested that the AudioID recognition system could pick up sound from a microphone and deliver relevant information associated with the sound. Identification relies on a published, open feature format to allow potential users to easily produce descriptive data for audio works of interest (for example, descriptions of newly released songs).

### BRIEF DESCRIPTION OF THE DRAWINGS

The inventions will be understood more fully from the detailed description given below and from the accompanying drawings of some embodiments of the inventions which, however, should not be taken to limit the inventions to the specific embodiments described, but are for explanation and understanding only.

FIG. 1 is a block diagram representation illustrating a system according to some embodiments of the inventions.

FIG. 2 is a block diagram representation of a flow chart according to some embodiments of the inventions.

### DETAILED DESCRIPTION

Some embodiments of the inventions relate to presentation of entertainment content in response to received ambient audio.

In some embodiments, an apparatus includes an acoustic analyzer to identify received ambient audio and a content parser to select entertainment content associated with the identified audio for presentation of the entertainment content to a user.

In some embodiments, a system includes an acoustic analyzer to identify received ambient audio, a content parser to select entertainment content associated with the identified audio, and a presentation device to present the selected entertainment content to a user.

In some embodiments an ambient audio signal is received, the received ambient audio signal is identified, and entertainment content associated with the identified ambient audio is selected for presentation to a user.

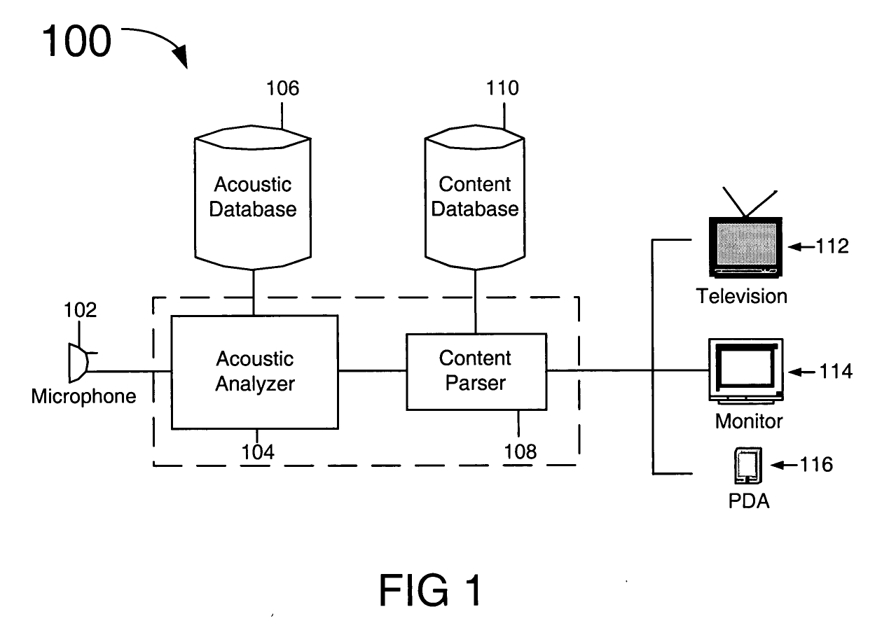

FIG. 1 illustrates a system 100 according to some embodiments. System 100 includes a microphone 102, an acoustic analyzer 104, an acoustic database 106, a content parser 108, a content database 110, and one or more presentation devices, including a television 112, a monitor 114 and a PDA (Personal Digital Assistant) 116.

Microphone 102 automatically detects ambient audio (real time streaming audio).

Acoustic analyzer 104 recognizes the ambient audio by consulting an acoustic database 106. This may be accomplished, for example, by fingerprinting the ambient audio and consulting the acoustic database 106 for a match with that audio fingerprint. Such fingerprinting techniques have been included, for example, in products of Audible Magic Corporation (Content-based identification API product) and Fraunhofer Institue of Integrated Circuits IIS (Automatic Identification/Fingerprinting of Audio) (AudioID System).

Audible Magic Corporation's content-based identification software may be used to scan a file or listen to an audio stream, derive fingerprints that will be used to identify the audio, and create an XML package that may be sent to a database that is used to provide positive identification information with a high level of data integrity using fingerprint information.

Fraunhofer's AudioID System performs an automatic identification/recognition of audio data based on a database of registered works and delivers the required information (that is, title or name of the artist) in real-time. Identification relies on a published, open feature format.

Once the acoustic analyzer has identified the ambient audio (for example, a song) received by the microphone 102 the content parser 108 accesses content database 110 to identify all entertainment content in that database that is associated with the identified audio. The content parser 108 can select for presentation all the identified entertainment content, randomly select for presentation some of the identified entertainment content and/or select for presentation some of the identified entertainment content based on certain selection criteria (for example, a selection by a user or a pre-selection of a certain type of content by a user, or selection or pre-selection of a certain type of content for certain audio or types of audio, time of day, day of the week, types of presentation devices currently available for use, and/or other options). One or more presentation devices are coupled to the content parser for presentation of the entertainment content to a user (in some embodiments at the same time as the user is listening to the ambient audio). FIG. 1 illustrates three types of presentation devices: television 112, monitor 114 and personal digital assistant 116. However, any combination of presentation devices (and arrangements with more than one of one type of presentation device) may be used. Examples of types of presentation devices that may be used according to some embodiments include any of the following or combination of the following: display, television, monitor, LCD, a small LCD (for example, a small LCD that is part of a stereo, hi-fi system, or car radio), computer, laptop, handheld device, cell phone, personal digital assistant, robot, automated toy, and audio speakers. Examples of types of entertainment content that may be presented according to some embodiments includes any of the following or combination of the following: pictorial, graphical, video, audio, audio-visual, textual, HTML, straight text, a textual document, straight text from the Internet (for example, from the Worldwide Web), and multimedia. Examples of entertainment content that may be presented according to some embodiments includes any of the following or combination of the following: music video, pictures, graphics, images, text, multimedia, a virtual DJ, a musical score, a moving toy, a stuffed animal, a moving robot, a computer desktop and a computer screensaver.

In some embodiments acoustic analyzer 104 and content parser 108 may be included in a single device illustrate by a dotted line in FIG. 1 (for example, a computer implemented in hardware and/or software). In some embodiments acoustic analyzer 104 and content parser 108 may each be implemented in either hardware, firmware, software and/or some combination thereof. In some embodiments such a computer may be a local computer local to the microphone 102 and the presentation devices 112, 114 and/or 116. In some embodiments such a computer may be a remote computer remote from the microphone 102 and the presentation devices 112, 114 and/or 116. In some embodiments the acoustic database 106 may be local to the acoustic analyzer 104, and in some embodiments the acoustic database 106 may be remote from the acoustic analyzer 104 (for example, coupled via a network connection, or accessible via the internet). In some embodiments the content database 110 may be local to the content parser 108, and in some embodiments the content database 110 may be remote from the content parser 108 (for example, coupled via a network connection, or accessible via the internet). In some embodiments the microphone 102 may be coupled to the rest of the system wirelessly. In some embodiments the presentation device (for example, television 112, monitor 114 and/or PDA 116) may be coupled to the rest of the system wirelessly.

In some embodiments a system such as system 100 can automatically listen to ambient audio, recognize it, and then provide associated entertainment for presentation to a user. In some embodiments the entertainment content is directly related to the ambient audio (for example, music) being played in a given area (for example, the song's music video). In some embodiments, while listening to a CD (compact disc) a user could turn on a television set, display and/or monitor on which a music video corresponding to the song being played (or video, pictures, or related data of a musical group playing the song, for example). In some embodiments, a web page may be opened on a computer that relates to ambient audio being played (for example, the musical group's web page, fan club web page or other web pages about the song and/or musical group). In some embodiments, for example, a user might come home and turn on a classical radio station playing a song such as Bach Aria. The screen saver of a user's computer suddenly begins showing pictures of Salzburg and/or other related Bach images, opens a web search (for example, using Google on Bach, Salzburg and/or Bach Aria), and/or shows a graphical musical score of the music being played (either accurate or merely generic to convey a musical mood). In some embodiments a child comes home, puts in his favorite CD, and his computer connected toy (for example, a robot or stuffed animal connected with a wire or wirelessly) begins to sing along with the song and/or dance to beat of the song. In some embodiments, alternative presentations can be provided. For example, additional drum beats are added to the song over some speakers, and/or additional drum beats are presented on a display, monitor, TV, etc. that gives the appearance that the computer, monitor, display, TV and/or other presentation device or attached peripheral are “jamming” with the beat.

In some embodiments the identification of the received ambient audio may be performed locally to the ambient audio, remote from the ambient audio, and/or some combination thereof. In some embodiments the selection of the content associated with the identified audio may be performed locally to the ambient audio, remote from the ambient audio, and/or some combination thereof. In some embodiments, the presentation of the content to a user may be performed locally to the ambient audio, remote from the ambient audio, and/or some combination thereof. In some embodiments, a listener listens to the ambient audio and receives a presentation of the content simultaneously. In some embodiments the presentation of the content is synchronized with the ambient audio (for example, the fingerprint of the audio includes a time stamp which may be used to synchronize the content presentation with the ambient audio).

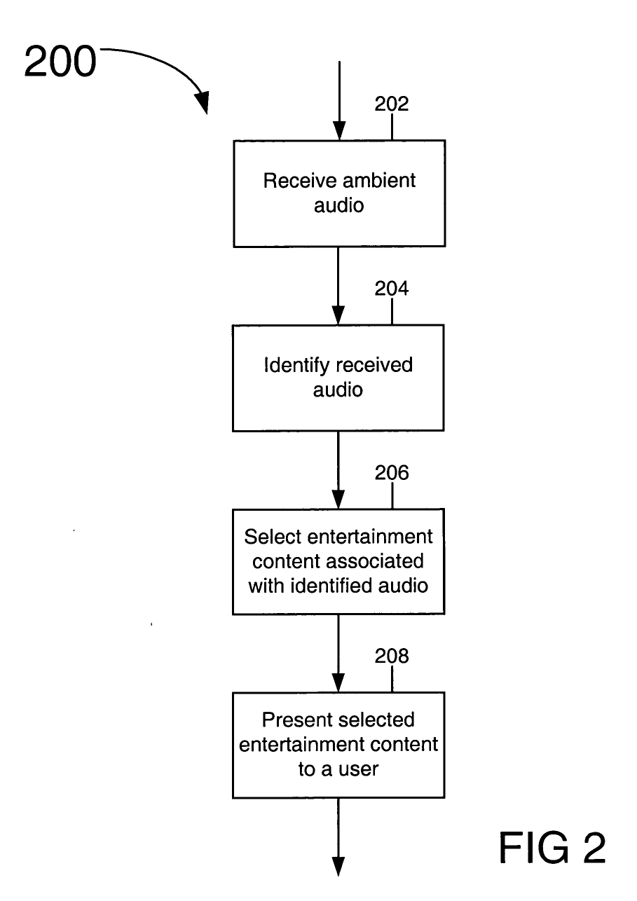

FIG. 2 illustrates a flow chart diagram 200 according to some embodiments. Ambient audio is received at 202. The received audio is identified at 204 (for example, using an acoustic analyzer 104 and/or an acoustic database 106 as illustrated in FIG. 1). The identified audio is used to select entertainment content associated with the audio at 206 (for example, using a content parser 108 and/or a content database 100 as illustrated in FIG. 1). The selected entertainment content is presented to a user at 208. In some embodiments the actual presentation at 208 is optional.

Although some embodiments have been described in reference to particular implementations such as using particular types of acoustic analyzers and/or content parsers and/or requiring remote or local databases for comparison, other implementations are possible according to some embodiments. Further, although some embodiments have been illustrated and discussed in which entertainment content is selected for presentation and/or presented to a user, in some embodiments any content is selected for presentation and/or presented to a user. In some embodiments informational content is selected and/or presented to a user (for example, a museum displaying information about a particular song or piece of music, composer, singer, writer, etc.)

In each system shown in a figure, the elements in some cases may each have a same reference number or a different reference number to suggest that the elements represented could be different and/or similar. However, an element may be flexible enough to have different implementations and work with some or all of the systems shown or described herein. The various elements shown in the figures may be the same or different. Which one is referred to as a first element and which is called a second element is arbitrary.

An embodiment is an implementation or example of the inventions. Reference in the specification to “an embodiment,” “one embodiment,” “some embodiments,” or “other embodiments” means that a particular feature, structure, or characteristic described in connection with the embodiments is included in at least some embodiments, but not necessarily all embodiments, of the inventions. The various appearances “an embodiment,” “one embodiment,” or “some embodiments” are not necessarily all referring to the same embodiments.

If the specification states a component, feature, structure, or characteristic “may”, “might”, “can” or “could” be included, for example, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

Although flow diagrams and/or state diagrams may have been used herein to describe embodiments, the inventions are not limited to those diagrams or to corresponding descriptions herein. For example, flow need not move through each illustrated box or state, or in exactly the same order as illustrated and described herein.

The inventions are not restricted to the particular details listed herein. Indeed, those skilled in the art having the benefit of this disclosure will appreciate that many other variations from the foregoing description and drawings may be made within the scope of the present inventions. Accordingly, it is the following claims including any amendments thereto that define the scope of the inventions.

1. An apparatus comprising:
an acoustic analyzer to identify received ambient audio; and
a content parser to select content associated with the identified audio for presentation of the content to a user.

2. The apparatus according to claim 1, further comprising a microphone to receive the ambient audio.

3. The apparatus according to claim 2, wherein the microphone is wirelessly coupled to the acoustic analyzer.

4. The apparatus according to claim 1, wherein the acoustic analyzer is to identify the received ambient audio by comparing it to audio stored in a database.

5. The apparatus according to claim 1, wherein the acoustic analyzer is to provide a fingerprint for the received ambient audio and to compare the fingerprint to fingerprints stored in a database.

6. The apparatus according to claim 1, wherein the content parser identifies content entries in a database corresponding to the identified audio.

7. The apparatus according to claim 1, wherein the content is of at least one the following types: pictorial, graphical, video, audio, audio-visual, textual, HTML, straight text, a textual document, straight text from the Internet, and multimedia.

8. The apparatus according to claim 1, wherein a user is able to select at least one type of the content for presentation.

9. The apparatus according to claim 1, wherein a user is able to pre-select at least one type of the content for presentation.

10. The apparatus according to claim 9, wherein the pre-selection may be different for different audio.

11. The apparatus according to claim 1, wherein the selected content may be presented on at least one of the following: display, television, monitor, LCD, a small LCD, computer, laptop, handheld device, cell phone, personal digital assistant, robot, automated toy, and audio speakers.

12. The apparatus according to claim 1, wherein the apparatus is a computer.

13. The apparatus according to claim 12, wherein the computer is local to where the ambient audio may be listened to by a user and to where the content may be received by a user.

14. The apparatus according to claim 12, wherein the computer is remote from where the ambient audio may be listened to by a user and from where the content may be received by a user.

15. The apparatus according to claim 1, wherein the content is presented remotely from the ambient audio.

16. The apparatus according to claim 1, wherein the content is at least one of a music video, pictures, images, graphics, text, multimedia, a virtual DJ, a musical score, a moving toy, a stuffed animal, a robot, a computer desktop and a computer screensaver.

17. The apparatus according to claim 1, wherein the user listens to the ambient audio and receives the presentation of the content simultaneously.

18. The apparatus according to claim 17, wherein the presentation of the content is synchronized with the ambient audio.

19. The apparatus according to claim 1, wherein the content is entertainment content.

20. A system comprising:
an acoustic analyzer to identify received ambient audio;
a content parser to select content associated with the identified audio; and
a presentation device to present the selected content to a user.

21. The system according to claim 20, further comprising a microphone to receive the ambient audio.

22. The system according to claim 21, wherein the microphone is wirelessly coupled to the acoustic analyzer.

23. The system according to claim 20, wherein the acoustic analyzer is to identify the received ambient audio by comparing it to audio stored in a database.

24. The system according to claim 20, wherein the acoustic analyzer is to provide a fingerprint for the received ambient audio and to compare the fingerprint to fingerprints stored in a database.

25. The system according to claim 20, wherein the content parser identifies content entries in a database corresponding to the identified audio.

26. The system according to claim 20, wherein the content is of at least one the following types: pictorial, graphical, video, audio, audio-visual, textual, HTML, straight text, a textual document, straight text from the Internet, and multimedia.

27. The system according to claim 20, wherein a user is able to select at least one type of the content for presentation.

28. The system according to claim 20, wherein a user is able to pre-select at least one type of the content for presentation.

29. The system according to claim 28, wherein the pre-selection may be different for different audio.

30. The system according to claim 20, wherein the presentation device is at least one of the following: display, television, monitor, LCD, a small LCD, computer, laptop, handheld device, cell phone, personal digital assistant, robot, automated toy, and audio speakers.

31. The system according to claim 20, wherein the acoustic analyzer and the content parser are included in a computer.

32. The system according to claim 31, wherein the computer is local to where the ambient audio may be listened to by a user and to where the content may be received by a user.

33. The system according to claim 31, wherein the computer is remote from where the ambient audio may be listened to by a user and from where the content may be received by a user.

34. The system according to claim 20, wherein the presentation device is to present the selected content to the user at a location remote from the ambient audio.

35. The system according to claim 20, wherein the display is wirelessly coupled to the content parser.

36. The system according to claim 20, wherein the content is at least one of a music video, pictures, graphics, images, text, multimedia, a virtual DJ, a musical score, a moving toy, a stuffed animal, a robot, a computer desktop and a computer screensaver.

37. The system according to claim 20, further comprising an acoustic database coupled to the acoustic analyzer and a content database coupled to the content parser.

38. The system according to claim 20, wherein the user listens to the ambient audio and receives the presentation of the content simultaneously.

39. The system according to claim 38, wherein the presentation of the content is synchronized with the ambient audio.

40. The system according to claim 20, wherein the content is entertainment content.

41. A method comprising:
receiving an ambient audio signal;
identifying the received ambient audio; and
selecting content associated with the identified ambient audio for presentation to a user.

42. The method according to claim 41, wherein the received ambient audio is identified by comparing it to audio stored in a database.

43. The method according to claim 41, further comprising:
providing a fingerprint for the received ambient audio; and
comparing the fingerprint to fingerprints stored in a database.

44. The method according to claim 41, wherein the content is identified by obtaining one or more entries in a database corresponding to the identified audio.

45. The method according to claim 41, wherein the content is of at least one the following types: pictorial, graphical, video, audio, audio-visual, textual, HTML, straight text, a textual document, straight text from the Internet, and multimedia.

46. The method according to claim 41, further comprising selecting at least one type of content for presentation.

47. The method according to claim 41, further comprising pre-selecting at least one type of content for presentation.

48. The method according to claim 47, wherein the pre-selection may be different for different audio.

49. The method according to claim 41, further comprising presenting the selected content.

50. The method according to claim 49, wherein the user listens to the ambient audio and receives the presentation of the content simultaneously.

51. The method according to claim 50, wherein the presentation of the content is synchronized with the ambient audio.

52. The method according to claim 41, wherein the content is entertainment content.

53. The method according to claim 41, further comprising presenting the selected content on at least one of the following devices: display, television, monitor, LCD, a small LCD, computer, laptop, handheld device, cell phone, personal digital assistant, robot, automated toy, and audio speakers.

54. The method according to claim 41, wherein the content is at least one of a music video, pictures, graphics, images, text, multimedia, a virtual DJ, a musical score, a moving toy, a stuffed animal, a robot, a computer desktop and a computer screensaver.
